(19) United States
(12) Patent Application Publication
(10) Pub. No.: US 2010/0283098 A1
(43) Pub. Date: Nov. 11, 2010

(54) NONVOLATILE SEMICONDUCTOR MEMORY DEVICE AND A METHOD OF MANUFACTURING THE SAME

(76) Inventors: Koji YOSHIDA, Niigata (JP); Keita TAKAHASHI, Nara (JP)

Correspondence Address: MCDERMOTT WILL & EMERY LLP, 600 13TH STREET, NW, WASHINGTON, DC, 20005-3096, US

(21) Appl. No.: 12/752,758

(22) Filed: Apr. 1, 2010

(30) Foreign Application Priority Data
May 8, 2009 (JP) 2009-113660

(51) Int. Cl. H01L 27/115; H01L 21/8246

(52) U.S. Cl. 257/324; 438/261; 257/E21.679; 257/E27.103

(57) ABSTRACT

A nonvolatile semiconductor memory device includes a plurality of bit line diffusion layers formed in a semiconductor region, and extending in a row direction; a plurality of first insulating films, each being formed on the semiconductor region and between adjacent two of the bit line diffusion layers, and including a charge trapping film; a plurality of bit line insulating films formed above the respective bit line diffusion layers; and a plurality of word lines formed above the semiconductor region to cover the first insulating films and the bit line insulating films, intersecting the bit line diffusion layers, and extending in a column direction. The bit line insulating films have smaller thicknesses than the first insulating films, and upper surfaces of the bit line insulating films are parallel to upper surfaces of the first insulating films.

### CROSS-REFERENCE TO RELATED APPLICATION

This application claims priority to Japanese Patent Application No. 2009-113660 filed on May 8, 2009, the disclosure of which including the specification, the drawings, and the claims is hereby incorporated by reference in its entirety.

### BACKGROUND

The present disclosure relates to nonvolatile semiconductor memory devices and methods of manufacturing the devices. More particularly, the present disclosure relates to nonvolatile semiconductor memory devices, which are provided in metal-oxide-nitride-oxide-silicon (MONOS) type nonvolatile semiconductor memory devices, and include bit line diffusion layers and trapping films for storing charge, and methods of manufacturing the devices.

A MONOS type nonvolatile semiconductor memory device stores charge in an oxide-nitride-oxide (ONO) film, in which a silicon dioxide film, a silicon nitride film, and a silicon dioxide film are sequentially formed. Until now, various types of MONOS type nonvolatile semiconductor memory devices have been suggested. In particular, attention has been given to a nonvolatile semiconductor memory element; which includes bit lines formed in a semiconductor substrate, ONO films formed over channel regions, and word lines formed on the bit lines to be orthogonal to the bit lines; and stores charge locally in the ONO films to store desired information. This is because the element is suited for increasing density, improving performance, and decreasing voltage (see, e.g., Japanese Patent Publication No. 2001-077220).

A method of manufacturing a conventional nonvolatile semiconductor memory device, in which bit lines are formed in a semiconductor substrate, will be described hereinafter with reference to FIGS. 7A-7G.

First, as shown in FIG. 7A, ONO films 202; each of which is a charge trapping film, and includes a first silicon dioxide (SiO₂) film 202a, a silicon nitride (SiN) film 202b, and a second silicon dioxide film 202c; are formed on a p-type semiconductor substrate 201.

Then, as shown in FIG. 7B, a resist pattern 203 for defining location of the plurality of bit lines is formed on the ONO films 202 by lithography.

Next, as shown in FIG. 7C, the second silicon dioxide films 202c and the silicon nitride films 202b of the ONO films 202 are removed using the resist pattern 203 as a mask. While the underlying first silicon dioxide films 202a are retained in this example, they are removed in some cases to expose the semiconductor substrate 201.

Thereafter, as shown in FIG. 7D, n-type impurity ions are implanted into the semiconductor substrate 201 through the first silicon dioxide films 202a using the resist pattern 203 as a mask. As such, a plurality of n-type diffusion layers 204 are formed in regions of the semiconductor substrate 201 under regions exposed from openings of the resist pattern 203.

Then, after removing the resist pattern 203 as shown in FIG. 7E, the diffusion layers 204 are subjected to enhanced oxidation as shown in FIG. 7F. As such, upper portions of the diffusion layers 204 are oxidized to form bit line insulating films 205, while activating the implanted impurity ions to form the plurality of bit lines from the diffusion layers 204.

Next, as shown in FIG. 7G, conductive polysilicon is deposited on the ONO films 202 and the bit line insulating films 205 to form word lines (electrodes) 206 made of polysilicon. In this manner, a nonvolatile semiconductor memory device is obtained.

### SUMMARY

After various studies, the present inventors found that the above-described conventional method of manufacturing a nonvolatile semiconductor memory device has the following problems.

Specifically, in the conventional method, the semiconductor substrate 201 is subjected to enhanced oxidation, thereby forming the bit line insulating films 205. Thus, as shown in FIGS. 8A and 8B, the diffusion layers 204 expand in a lateral direction during heat treatment due to the enhanced diffusion. This causes difficulty in miniaturization of a memory cell.

Furthermore, upper surfaces of the bit line insulating films 205 are raised higher than upper surfaces of the ONO films 202. Thus, when patterning the conductive polysilicon forming the word lines 206, differences in level occur in portions of polysilicon, which are formed on the bit line insulating films 205. As shown in FIG. 8A, these level differences cause constricted portions 206a in the word lines 206. The constricted portions 206a increase resistance of the word lines 206, and moreover, cause disconnection. Furthermore, residues 206b of polysilicon 206 occur in the raised portions, which cause problems such as shorting between the adjacent word lines 206.

It is an objective of the present disclosure to solve the above problems and miniaturize a memory cell including charge trapping films, while reducing shorting between word lines (electrodes).

In order to achieve the above-described objective, the present disclosure provides a method of manufacturing a nonvolatile semiconductor memory device, in which bit line diffusion layers are not oxidized, and charge trapping films are selectively oxidized. This structure forms bit line insulating films above the bit line diffusion layers to be thinner and flatter than insulating films including the charge trapping films.

Specifically, the nonvolatile semiconductor memory device according to the present disclosure includes a plurality of bit line diffusion layers formed in a semiconductor region, and extending in a row direction; a plurality of first insulating films, each being formed on the semiconductor region and between adjacent two of the bit line diffusion layers, and including a charge trapping film; a plurality of bit line insulating films formed above the respective bit line diffusion layers; and a plurality of word lines formed above the semiconductor region to cover the first insulating films and the bit line insulating films, intersecting the bit line diffusion layers, and extending in a column direction. The bit line insulating films have smaller thicknesses than the first insulating films, and upper surfaces of the bit line insulating films are parallel to upper surfaces of the first insulating films.

The device according to the present disclosure reduces differences in level, which occur in surfaces of the bit line insulating films when being manufactured. This improves processing yields of the word lines formed on the bit line insulating films having reduced level differences, thereby decreasing shorting between the word lines.

The device of the present disclosure may further include second insulating films formed between the first insulating films and the word lines, and between the bit line insulating films and the word lines.

In this structure, the second insulating films provide an advantage corresponding to an increase in the thicknesses of the bit line insulating films to increase electrical breakdown voltages of the bit line insulating films. In addition, with the increase in the distance between ends of the charge trapping films and the word lines, a process margin against a decrease in data retention capabilities of the memory cell is increased. This improves reliability of the nonvolatile semiconductor memory device.

In this case, each of the second insulating films may be a single layer film made of one of silicon dioxide, aluminum oxide, and hafnium oxide; or a multilayer film formed by stacking at least two thereof.

In the device of the present disclosure, the charge trapping films and the bit line insulating films may contain nitrogen.

In this case, the charge trapping films may contain silicon nitride, and the bit line insulating films may be made of silicon dioxide containing nitrogen.

In the device of the present disclosure, the bit line insulating films may have thicknesses of 10 nm or more.

In the device of the present disclosure, each of the first insulating films is an ONO film, in which a first silicon dioxide film, a silicon nitride film having a function of trapping charge, and a second silicon dioxide film are sequentially stacked.

A method of manufacturing a nonvolatile semiconductor memory device according to the present disclosure includes the steps of (a) forming on a semiconductor region, first insulating films, each of which includes a charge trapping film therein; (b) forming on the first insulating films, a mask film including a plurality of opening patterns extending in a row direction; (c) forming in upper portions of the semiconductor region, a plurality of bit line diffusion layers extending in the row direction by implanting impurity ions into the semiconductor region using the mask film; (d) exposing the charge trapping films from the first insulating films by etching exposed portions from the mask film in the first insulating films; (e) after the step (d), obtaining bit line insulating films from exposed portions from the first insulating films in the charge trapping films by performing thermal oxidation of the exposed portions in the charge trapping films so that the exposed portions in the charge trapping films lose charge trapping capability; and (f) forming above the semiconductor region, a plurality of word lines covering the first insulating films and the bit line insulating films, intersecting the bit line diffusion layers, and extending in a column direction.

According to the method of the present disclosure, the semiconductor region is not oxidized when forming the bit line insulating films. This reduces lateral expansion of the bit line diffusion layers, thereby enabling miniaturization of a memory cell. Furthermore, the charge trapping films themselves are selectively oxidized. Thus, the bit line insulating films have smaller thicknesses than the first insulating films, and upper surfaces of the bit line insulating films are substantially parallel to upper surfaces of the first insulating films. This reduces the level differences occurring in the surfaces of the bit line insulating films to improve processing yields of the word lines formed on the bit line insulating films. Therefore, shorting between the word lines can be reduced.

In the method according to the present disclosure, the step (c) may be performed between the steps (d) and (e).

As such, through the step (d), the thicknesses of the first insulating films are reduced to decrease the lateral expansion of the bit line diffusion layers caused by ion implantation. This facilitates further miniaturization of the memory cell.

The method of the present disclosure may further include between the steps (e) and (f), the step (g) forming second insulating films between the first insulating films and the word lines, and between the bit line insulating films and the word lines.

As such, the second insulating films provide an advantage corresponding to an increase in the thicknesses of the bit line insulating films to increase electrical breakdown voltages of the bit line insulating films. In addition, with the increase in the distance between ends of the charge trapping films and the word lines, a process margin against a decrease in data retention capabilities of the memory cell is increased. This improves reliability of the nonvolatile semiconductor memory device.

In this case, each of the second insulating films may be a single layer film of one of silicon dioxide, aluminum oxide, and hafnium oxide; or a multilayer film formed by stacking at least two thereof.

According to the method of the present disclosure, in the step (e), the bit line insulating films may be formed by in-situ steam generation (ISSG) for generating water vapor from hydrogen and oxygen introduced into the semiconductor region.

As such, when the bit line insulating films are formed by oxidizing the charge trapping films by ISSG, and the charge trapping films exposed from the first insulating films are made of silicon nitride; the charge trapping films lose charge trapping capability, and obtain stable insulating properties. Furthermore, unlike conventional thermal oxidation, ISSG oxidizes silicon nitride at a relatively high rate, and does not require a high temperature or a long time. Therefore, the diffusion layers do not expand in the lateral direction.

In this case, in the step (e), molar concentration of hydrogen used for the in-situ steam generation may range from 0.1% to 50%.

Furthermore, in this case, in the step (e), the in-situ steam generation may be performed at a heat treatment temperature ranging from 800° C. to 1050° C.

According to the method of the present disclosure, in the step (e), the bit line insulating films may be formed by heat treatment in an atmosphere including oxygen and a halogen compound instead of the in-situ steam generation.

In this case, in the step (e), the halogen compound may contain a fluorine compound, and molar concentration of the fluorine compound may range from 50 ppm to 500 ppm.

In this case, the fluorine compound may contain nitrogen trifluoride.

Furthermore, in this case, in the step (e), the halogen compound may contain a chloride compound, and molar concentration of the chloride compound may range from 1% to 10%.

In this case, the chloride compound may contain at least one of trichloroethylene, dichlorosilane, hydrogen chloride, and carbon tetrachloride.

In the method of the present disclosure, each of the charge trapping films may include a silicon nitride film, and the bit line insulating films may be silicon dioxide films containing nitrogen.

In the method of the present disclosure, each of the first insulating films may be an ONO film, in which a first silicon dioxide film, a silicon nitride film having a function of trapping charge, and a second silicon dioxide film are sequentially stacked.

As described above, the nonvolatile semiconductor memory device and the method of manufacturing the device according to the present disclosure reduces the lateral expansion of the bit line diffusion layers, thereby enabling miniaturization of the memory cell. Furthermore, since the bit line insulating films can be formed thinner than the insulating films including the trapping films, the level differences formed in the surfaces of the bit line insulating films can be reduced to improve processing yields of the word lines. This reduces shorting between the word lines.

### BRIEF DESCRIPTION OF THE DRAWINGS

FIG. 1 is a partial sectional view of a nonvolatile semiconductor memory device according to an example embodiment.

FIGS. 2A-2G are cross-sectional views illustrating a sequence of steps in a method of manufacturing the nonvolatile semiconductor memory device according to the example embodiment.

FIG. 3 is a graph showing that a growth rate of a silicon dioxide film grown on a silicon nitride film is faster than in conventional thermal oxidation, when the silicon dioxide film is oxidized in an atmosphere added with a halogen compound (NF₃).

FIG. 4 is a partial sectional view of a nonvolatile semiconductor memory device according to a variation of the example embodiment.

FIGS. 5A and 5B illustrate the nonvolatile semiconductor memory device according to the example embodiment. FIG. 5A is a schematic diagram illustrating movement of holes when a positive bias voltage is applied to the word lines. FIG. 5B is a graph illustrating time dependency of a threshold voltage.

FIGS. 6A and 6B illustrate the nonvolatile semiconductor memory device according to the variation of the example embodiment. FIG. 6A is a schematic diagram illustrating movement of electrons when a positive bias voltage is applied to the word lines. FIG. 6B is a graph illustrating time dependency of a threshold voltage.

FIGS. 7A-7G are cross-sectional views illustrating a sequence of steps in a conventional method of manufacturing a MONOS type nonvolatile semiconductor memory device.

FIG. 8A is a plan view of a conventional MONOS type nonvolatile semiconductor memory device. FIG. 8B is a cross-sectional view taken along the line VIIIb-VIIIb in FIG. 8A. FIG. 8C is a cross-sectional view taken along the line VIIIc-VIIIc in FIG. 8A.

### DETAILED DESCRIPTION

### Example Embodiment

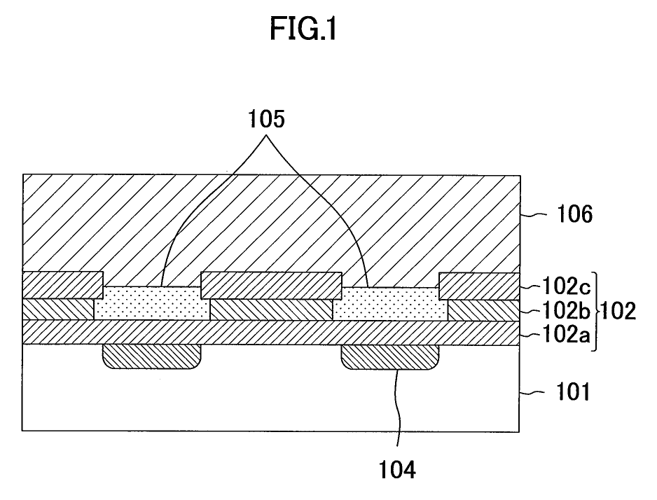

A nonvolatile semiconductor memory device according to an example embodiment will be described hereinafter with reference to FIG. 1.

As shown in FIG. 1, n-type diffusion layers (bit line diffusion layers) 104, which are spaced apart from each other and extend in a row direction (in the front-back direction of the figure), are formed in upper portions of a semiconductor substrate 101 made of, e.g., p-type silicon (Si). First silicon dioxide (SiO₂) films 102a with thicknesses of about 5 nm are formed on a main surface of the semiconductor substrate 101. Silicon nitride (SiN) films 102b with thicknesses of about 7 nm and second silicon dioxide films 102c with thicknesses of about 10 nm are sequentially formed on the first silicon dioxide films 102a and in regions except for regions above the n-type diffusion layers 104 (over channel regions). The first silicon dioxide films 102a, the silicon nitride films 102b, and the second silicon dioxide films 102c constitute oxide-nitride-oxide (ONO) films 102 having a function of trapping charge.

As a feature of this example embodiment, the silicon nitride films 102b are oxidized on the first silicon dioxide films 102a and above the n-type diffusion layers 104 to form bit line insulating films 105 with thicknesses of about 8 nm and made of silicon dioxide.

A plurality of word lines (gate electrodes) 106; which intersect the n-type diffusion layers 104, extend in a column direction (in the left-right direction of the figure), and are made of conductive polysilicon; are formed on the ONO films 102 and the bit line insulating films 105.

In this example embodiment, the bit line insulating films 105 above the n-type diffusion layers 104, which are bit line diffusion layers, are formed by selectively oxidizing the silicon nitride films 102b in the ONO films 102 to lose charge trapping capability instead of performing oxidation (enhanced oxidation) of the upper portions of the n-type diffusion layers 104. This reduces lateral expansion of the n-type diffusion layers 104, thereby enabling miniaturization of a memory cell. Furthermore, since the bit line insulating films 105 can be formed thinner than the ONO films 102, the level differences occurring in the surfaces of the bit line insulating films 105 can be reduced. This hardly causes constricted portions and disconnection in the word lines 106. Furthermore, due to reduction in the level differences in the surface, residues of polysilicon constituting the word lines hardly occur. This improves processing yields of the word lines 106, thereby reducing shorting between the word lines 106.

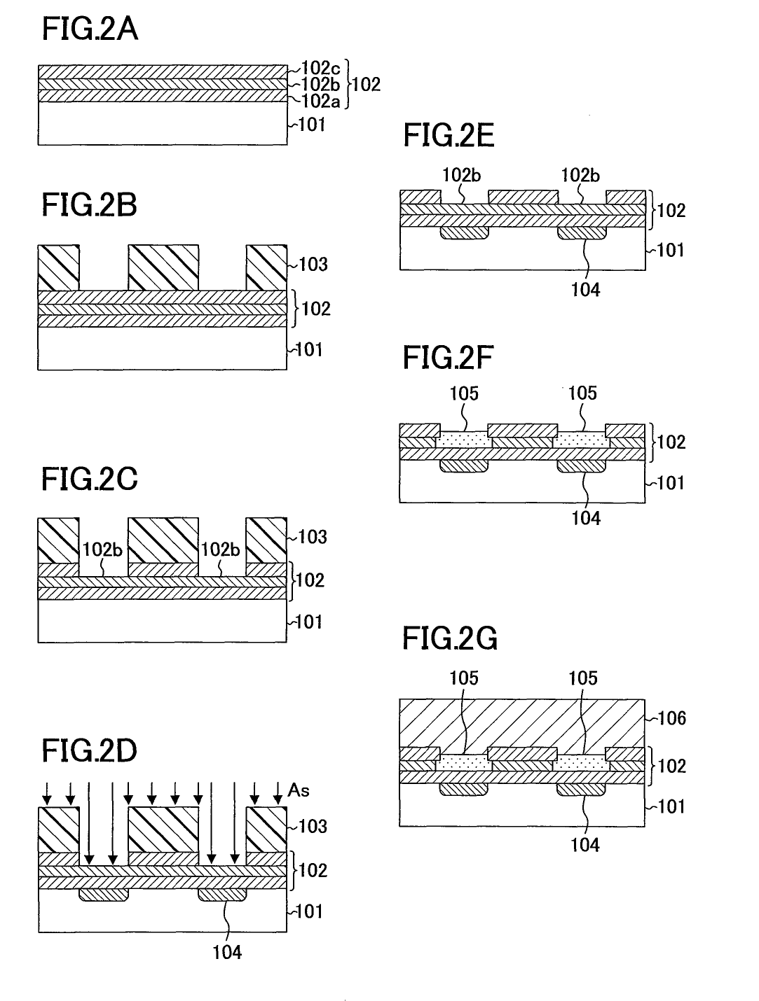

A method of manufacturing the nonvolatile semiconductor memory device having the above-described structure will be described hereinafter with reference to FIGS. 2A-2G.

First, as shown in FIG. 2A, the main surface of the semiconductor substrate 101 made of p-type silicon is thermally oxidized in an oxidizing atmosphere at a temperature of, e.g., about 1,000° C. so as to form the first silicon dioxide films 102a with the thicknesses of about 5 nm on the main surface of the semiconductor substrate 101. Then, the silicon nitride films 102b with thicknesses of about 15 nm, which serve as charge trapping films, are deposited on the first silicon dioxide films 102a by low pressure chemical vapor deposition (LPCVD) at, e.g., a deposition temperature of about 700° C. Furthermore, the deposited silicon nitride films 102b are thermally oxidized in an oxidizing atmosphere at a temperature of about 1,000° C. so as to form the second silicon dioxide films 102c with the thicknesses of about 10 nm in upper portions of the silicon nitride films 102b. As such, the ONO films 102; each of which includes the first silicon dioxide film 102a with the thickness of about 5 nm, the silicon nitride film 102b with the thickness reduced to about 7 nm, and the second silicon dioxide film 102c with the thickness of about 10 nm; are obtained on the main surface of the semiconductor substrate 101.

Then, as shown in FIG. 2B, a resist pattern 103, which defines formation regions of bit lines (n-type diffusion layers), is formed on the ONO films 102 by lithography.

Next, as shown in FIG. 2C, the ONO films 102 are subjected to dry etching with etching gas containing fluorocarbon (e.g., CF₄) as a major component, using the formed resist pattern 103 as a mask. In etching, the upper portions of the formation regions of the bit lines in the second silicon dioxide films 102c are removed to form a plurality of openings in the second silicon dioxide films 102c. This exposes the silicon nitride films 102b from the second silicon dioxide films 102c. For etching the second silicon dioxide films 102c, wet etching with hydrofluoric acid (HF) may be used instead of dry etching.

Thereafter, as shown in FIG. 2D, arsenic (As) ions being n-type impurities are implanted into the semiconductor substrate using the resist pattern 103 as a mask, under implantation conditions at, e g , implantation energy of about 50 keV and at an implantation dose of about 3×10¹⁵ cm⁻². This forms the plurality of n-type diffusion layers 104 serving as the bit lines in the upper portions of the semiconductor substrate 101. Note that ion implantation may be performed in the step shown in FIG. 2B, i.e., without etching the second silicon dioxide films 102c. However, in order to reduce the expansion of the n-type diffusion layers 104 in a lateral direction (a direction parallel to the main surface of the substrate) caused by the ion implantation, the ONO films 102 are preferably ion-implanted with reduced thicknesses as shown in FIG. 2D.

Next, as shown in FIG. 2E, the resist pattern 103 is removed by ashing in an oxidizing atmosphere and then, washing with a mixed solution of ammonia water (NH₄OH) and oxygenated water (H₂O₂).

Then, as shown in FIG. 2F, oxygen (O₂) added with about 0.1%-50% of hydrogen (H₂) at a temperature of, e.g., about 800° C-1050° C., is directly introduced into the semiconductor substrate 101. Furthermore, the silicon nitride films 102b, which are exposed from the openings of the second silicon dioxide films 102c, are selectively oxidized on the heated semiconductor substrate 101 by in-situ steam generation (ISSG) for generating water vapor from the introduced hydrogen and oxygen. As such, oxidized bit lines 105 with thicknesses of about 8 nm are formed on the first silicon dioxide films 102a. The bit line insulating films 105 preferably have thicknesses of 10 nm or more including the first silicon dioxide films 102a with the thicknesses of about 5 nm so as to reduce leak current, even when a voltage of 10 V for writing and erasing in the memory cell is applied. However, the thicknesses of the bit line insulating films 105 need to be smaller than the thicknesses of the ONO films 102, which serve as gate insulating films between adjacent memory cells. Note that the bit line insulating films 105 may have smaller thicknesses, when the voltage for wiring and erasing can be reduced to the voltage applying an electric field of 10 MV/cm as a limit.

As described above, in this example embodiment, the silicon nitride films 102b constituting the ONO films 102 are oxidized by ISSG to form the bit line insulating films 105. Thus, in the upper regions of the n-type diffusion layers 104 serving as the bit lines, the silicon nitride films 102b serving as the charge trapping films lose charge trapping capability. That is, excessive charge is not stored on the n-type diffusion layers 104 when writing and erasing, thereby obtaining stable operational properties.

Unlike conventional thermal oxidation, ISSG oxidizes the silicon nitride films 102b at a relatively high rate, and does not require a high temperature or a long time. Furthermore, surfaces of the n-type diffusion layers 104 after oxidizing the silicon nitride films 102b are not subjected to enhanced oxidation, and the n-type diffusion layers 104 do not expand in the lateral direction. This enables miniaturization of the memory cell, and reduction in punch-through problems. Moreover, since the n-type diffusion layers 104 are not subjected to enhanced diffusion, oxidized upper and lower surfaces of the bit line insulating films 105 are substantially parallel to the upper surfaces of the ONO films 102.

Instead of ISSG, thermal oxidation may be used to oxidize the silicon nitride films 102b. The thermal oxidation may be performed at a temperature of about 950° C. and in an atmosphere, in which oxygen (O₂) is mixed with a fluorine compound (e.g., nitrogen trifluoride (NF₃)) having molar concentration of about 50 ppm-500 ppm (preferably about 200 ppm). In this manner, the silicon nitride films 102b exposed from the openings of the second silicon dioxide films 102c can be also selectively oxidized.

This fact is supported by experimental data shown in FIG. 3. As shown in FIG. 3, when being oxidized in an atmosphere added with a halogen compound (e.g., nitrogen trifluoride (NF₃)), a silicon dioxide film on a silicon nitride film grows faster than in conventional thermal oxidation (see, e.g., R. Jaccodine et al. “Chemically Assisted Oxidation of Silicon Nitride,” Journal of the Electrochemical Society, 146(11), pp.4194-4195 (1999)). Note that, for thermal oxidation in the atmosphere of the fluorine compound, a chloride compound (e.g., trichloroethylene (C₂HCl₃), dichiorosilane (SiH₂Cl₂), hydrogen chloride (HCl) or carbon tetrachloride (CCl₄)) having molar concentration of about 1%-10% may be used instead of nitrogen trifluoride.

As long as the n-type diffusion layers 104 sufficiently function as the bit lines, the semiconductor substrate 101 (the n-type diffusion layers 104) may be slightly oxidized when forming the bit line insulating films 105.

Also, arsenic ions implanted into the n-type diffusion layers 104 are activated as donors by heat treatment for forming the bit line insulating films 105.

The bit line insulating films 105 necessarily contain nitrogen, since they are formed by oxidizing the silicon nitride films 102b being the charge trapping films.

Next, as shown in FIG. 2G, a conductive film made of conductive polysilicon is deposited on the ONO films 102 and the bit line insulating films 105 by, e.g., chemical vapor deposition (CVD). Then, the conductive film is patterned into a predetermined shape by lithography and dry etching to form the plurality of the word lines (gate electrodes) 106 from the conductive film.

As described above, according to this example embodiment, the silicon nitride films 102b being the charge trapping films are selectively oxidized above the n-type diffusion layers 104 serving as the bit lines, thereby forming the bit line insulating films 105. Thus, the n-type diffusion layers 104 are hardly oxidized to reduce the lateral expansion of the n-type diffusion layers 104. This enables miniaturization of the memory cell. Furthermore, since the thicknesses of the bit line insulating films 105 are not larger than that of the ONO films 102, the level differences generated in the surfaces of the bit line insulating films 105 are reduced. This reduces constriction or disconnection of the word lines, thereby improving processing yields of the word lines 106.

### Variation of Example Embodiment

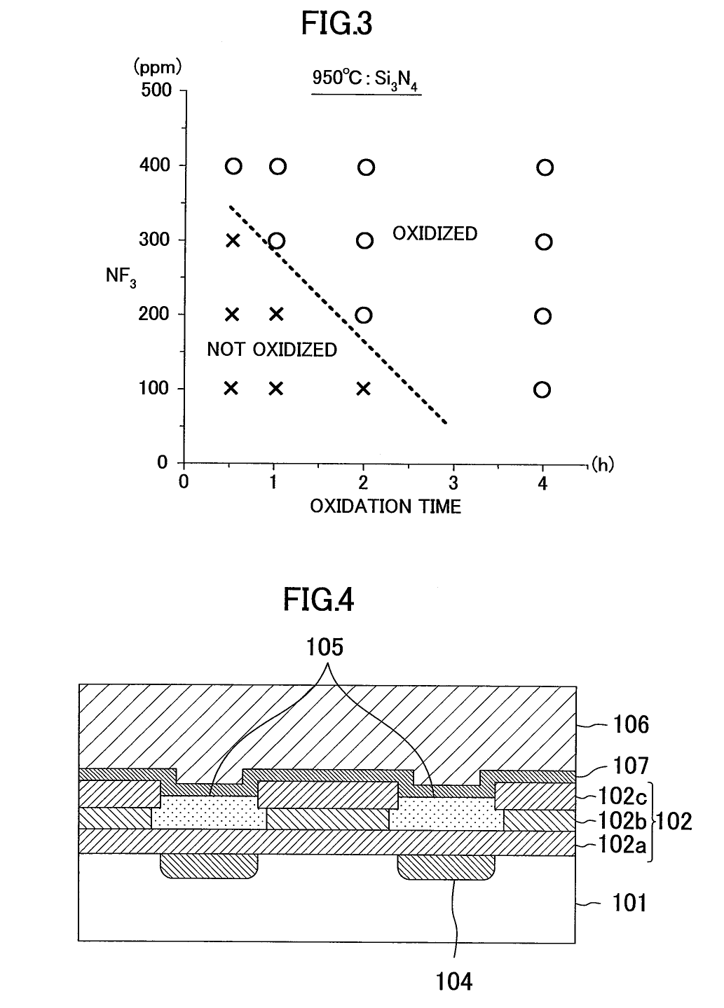

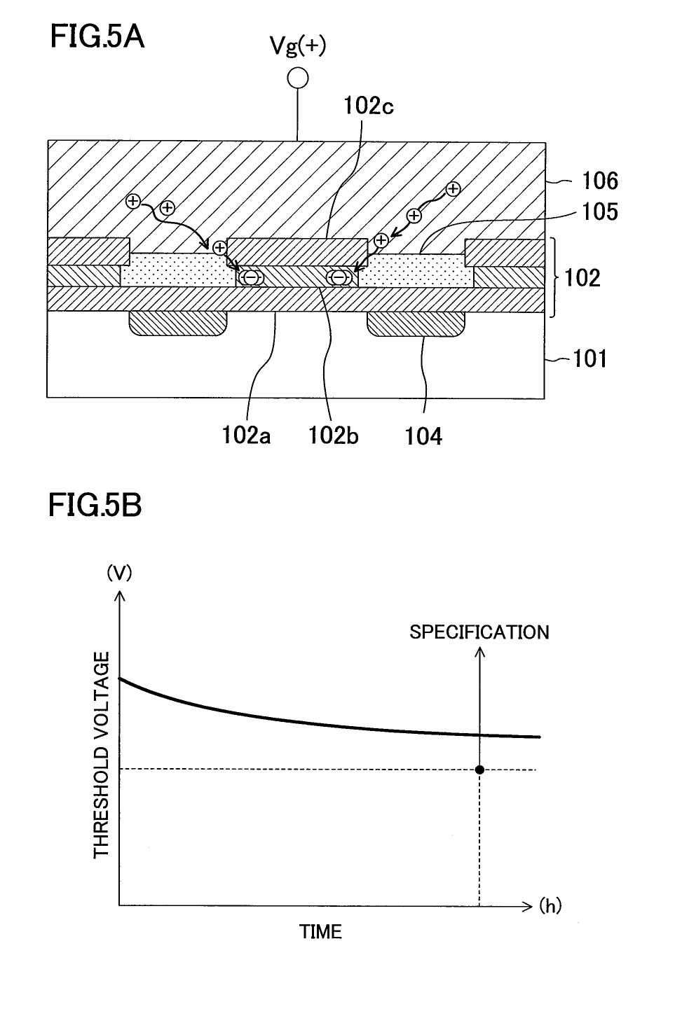

FIG. 4 illustrates a variation of the example embodiment.

As shown in FIG. 4, in a nonvolatile semiconductor memory device according to this variation, third silicon dioxide films 107 are formed on the ONO films 102 and the bit line insulating films 105. The word lines 106 are formed to include the third silicon dioxide films 107. Note that, high-k films made of e.g., aluminum oxide (AlO) or hafnium oxide (HfO) may be used for the third silicon dioxide films 107 instead of silicon dioxide.

In this variation, the third silicon dioxide films 107 substantially increase the thicknesses of the bit line insulating films 105, compared to the example embodiment. This increases electrical breakdown voltages of the bit line insulating films 105. In addition, with the increase in the distance between ends of the silicon nitride films 102b in the ONO films 102 and the word lines 106, a process margin against a decrease in data retention capabilities of the memory cell is increased. This improves reliability of the nonvolatile semiconductor memory device.

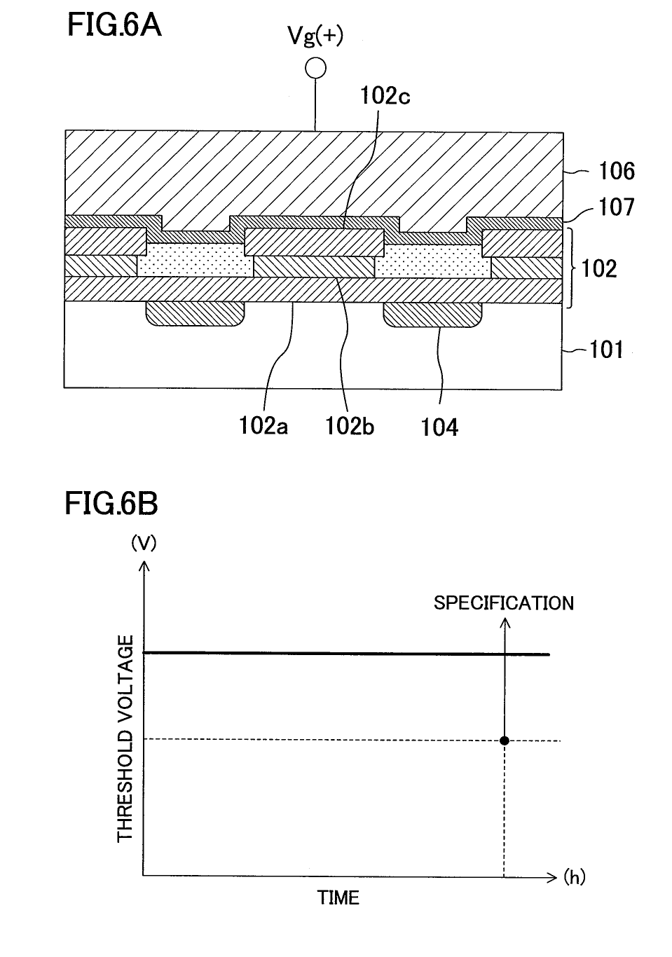

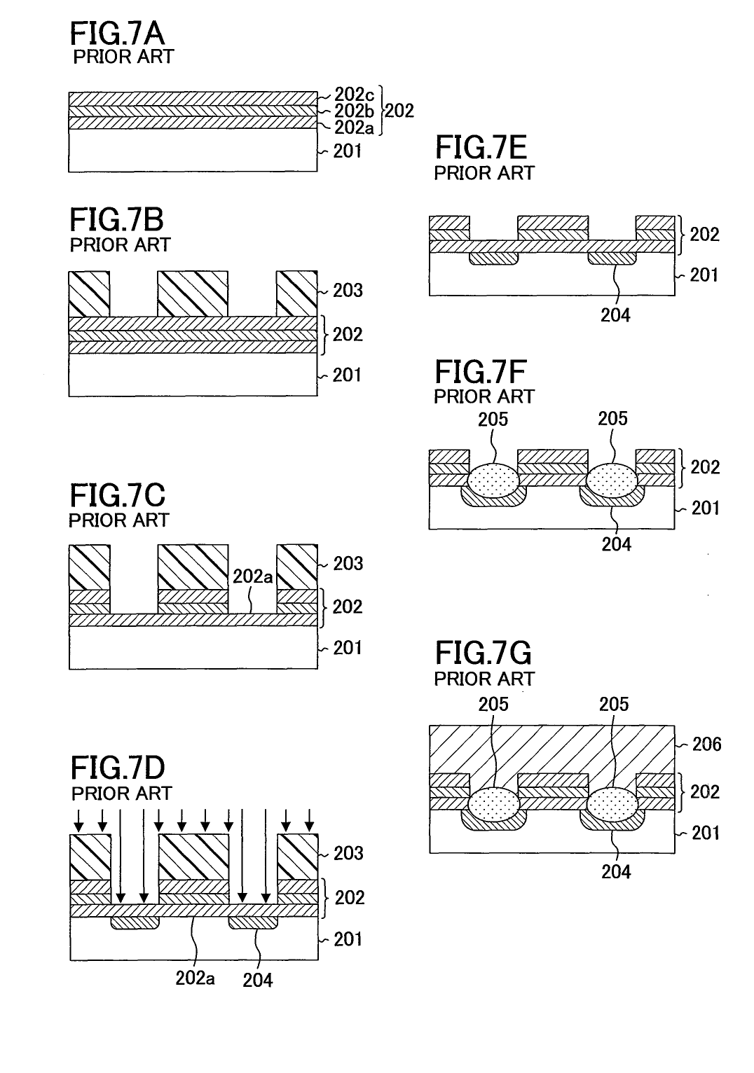

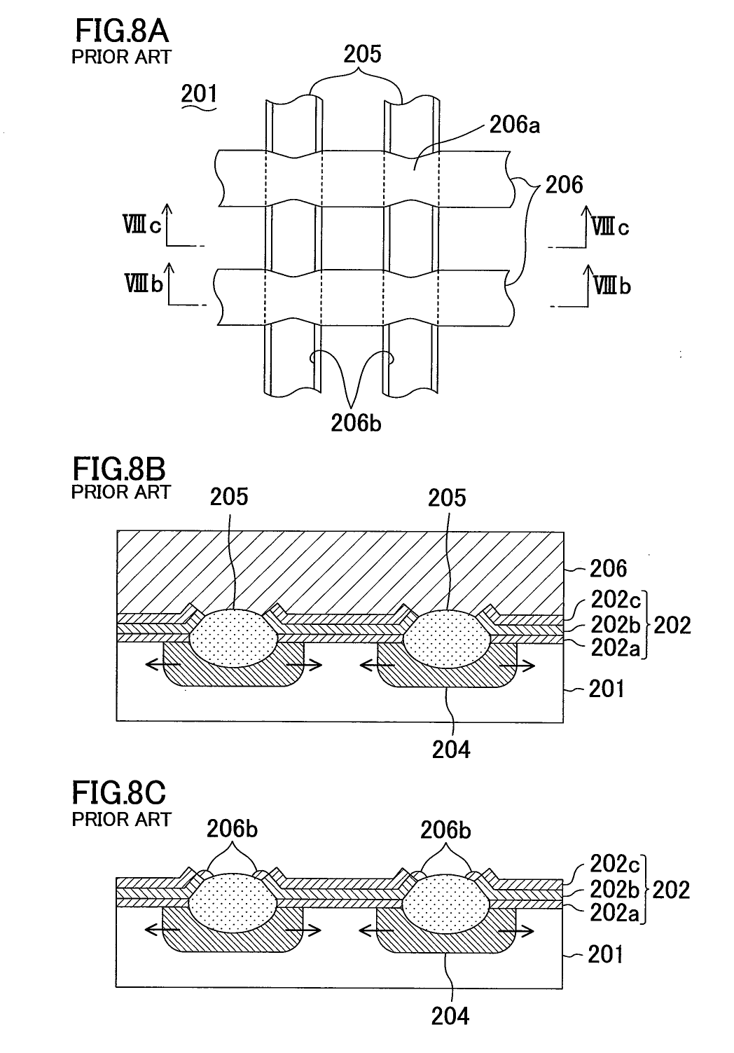

Specifically, in the nonvolatile semiconductor memory device according to the example embodiment shown in FIG. 5A, when a positive bias voltage is applied to the word lines 106 in a read operation, holes are introduced from the word lines 106 into the silicon nitride films 102b through the ends of the films, and the introduced holes neutralize the trapped electrons. As a result, there is slight concern that a threshold voltage of the memory cell fluctuates to change the programming state of the memory cell as shown in FIG. 5B. On the other hand, in this variation shown in FIG. 6A, since the third silicon dioxide films 107 are provided between the word lines 106 and the silicon nitride films 102b, dielectric strength between the word lines 106 and the silicon nitride films 102b is increased. Thus, as shown in FIG. 6B, the threshold voltage of the memory cell hardly fluctuates, thereby increasing a margin against the fluctuation in the threshold voltage of the memory cell.

While, in the example embodiment and the variation, p-type silicon (Si) is used for the semiconductor substrate 101, the semiconductor substrate may be made of n-type silicon, which has the opposite conductivity type.

As described above, the nonvolatile semiconductor memory device and the method of manufacturing the device according to the present disclosure enable miniaturization of a memory cell. In addition, since the bit line insulating films can be formed thinner than the insulating films including the trapping films, processing yields of the word lines are improved. Therefore, the present disclosure is useful particularly for a nonvolatile semiconductor memory device, which is provided in a MONOS type nonvolatile semiconductor memory device, and includes charge trapping films and bit line diffusion layers.

What is claimed is:

1. A nonvolatile semiconductor memory device comprising:
a plurality of bit line diffusion layers formed in a semiconductor region, and extending in a row direction;
a plurality of first insulating films, each being formed on the semiconductor region and between adjacent two of the bit line diffusion layers, and including a charge trapping film;
a plurality of bit line insulating films formed above the respective bit line diffusion layers; and
a plurality of word lines formed above the semiconductor region to cover the first insulating films and the bit line insulating films, intersecting the bit line diffusion layers, and extending in a column direction, wherein
the bit line insulating films have smaller thicknesses than the first insulating films, and upper surfaces of the bit line insulating films are parallel to upper surfaces of the first insulating films.

2. The device of claim 1, further comprising
second insulating films formed between the first insulating films and the word lines, and between the bit line insulating films and the word lines.

3. The device of claim 2, wherein
each of the second insulating films is a single layer film made of one of silicon dioxide, aluminum oxide, and hafnium oxide; or a multilayer film formed by stacking at least two thereof.

4. The device of claim 1, wherein
the charge trapping films and the bit line insulating films contain nitrogen.

5. The device of claim 4, wherein
the charge trapping films contains silicon nitride, and
the bit line insulating films are made of silicon dioxide containing nitrogen.

6. The device of claim 1, wherein
the bit line insulating films have thicknesses of 10 nm or more.

7. The device of claim 1, wherein
each of the first insulating films is an ONO film, in which a first silicon dioxide film, a silicon nitride film having a function of trapping charge, and a second silicon dioxide film are sequentially stacked.

8. A method of manufacturing of a nonvolatile semiconductor memory device comprising the steps of:
(a) forming on a semiconductor region, first insulating films, each of which includes a charge trapping film therein;
(b) forming on the first insulating films, a mask film including a plurality of opening patterns extending in a row direction;
(c) forming in upper portions of the semiconductor region, a plurality of bit line diffusion layers extending in the row direction by implanting impurity ions into the semiconductor region using the mask film;
(d) exposing the charge trapping films from the first insulating films by etching exposed portions from the mask film in the first insulating films;
(e) after the step (d), obtaining bit line insulating films from exposed portions from the first insulating films in the charge trapping films by performing thermal oxidation of the exposed portions in the charge trapping films so that the exposed portions in the charge trapping films lose charge trapping capability; and
(f) forming above the semiconductor region, a plurality of word lines covering the first insulating films and the bit line insulating films, intersecting the bit line diffusion layers, and extending in a column direction.

9. The method of claim 8, wherein
the step (c) is performed between the steps (d) and (e).

10. The method of claim 8, further comprising between the steps (e) and (f),
the step (g) forming second insulating films between the first insulating films and the word lines, and between the bit line insulating films and the word lines.

11. The method of claim 10, wherein
each of the second insulating films is a single layer film of one of silicon dioxide, aluminum oxide, and hafnium oxide; or a multilayer film formed by stacking at least two thereof.

12. The method of claim 8, wherein
in the step (e), the bit line insulating films are formed by in-situ steam generation (ISSG) for generating water vapor from hydrogen and oxygen introduced into the semiconductor region.

13. The method of claim 12, wherein
in the step (e), molar concentration of hydrogen used for the in-situ steam generation ranges from 0.1% to 50%.

14. The method of claim 12, wherein
in the step (e), the in-situ steam generation is performed at a heat treatment temperature ranging from 800° C. to 1050° C.

15. The method of claim 8, wherein
in the step (e), the bit line insulating films are formed by heat treatment in an atmosphere including oxygen and a halogen compound.

16. The method of claim 15, wherein
in the step (e), the halogen compound contains a fluorine compound, and
molar concentration of the fluorine compound ranges from 50 ppm to 500 ppm.

17. The method of claim 16, wherein
the fluorine compound contains nitrogen trifluoride.

18. The method of claim 15, wherein
in the step (e), the halogen compound contains a chloride compound, and
molar concentration of the chloride compound ranges from 1% to 10%.

19. The method of claim 18, wherein
the chloride compound contains at least one of trichloroethylene, dichlorosilane, hydrogen chloride, and carbon tetrachloride.

20. The method of claim 8, wherein
each of the charge trapping films includes a silicon nitride film, and
the bit line insulating films are silicon dioxide films containing nitrogen.

21. The method of claim 8, wherein
each of the first insulating films is an ONO film, in which a first silicon dioxide film, a silicon nitride film having a function of trapping charge, and a second silicon dioxide film are sequentially stacked.
